(19) United States
(12) Patent Application Publication
(10) Pub. No.: US 2020/0407215 A1
(43) Pub. Date: Dec. 31, 2020

(54) MEMS MICROPHONE AND MOBILE TERMINAL

(71) Applicant: AAC ACOUSTIC TECHNOLOGIES (SHENZHEN) CO., LTD., Shenzhen city (CN)

(72) Inventors: Peng Zeng, Shenzhen (CN); Hengbin Hu, Shenzhen (CN)

(21) Appl. No.: 16/945,930

(22) Filed: Aug. 2, 2020

Related U.S. Application Data
(63) Continuation of application No. PCT/CN2019/094065, filed on Jun. 30, 2019.

(51) Int. Cl. B81B 7/00; H04R 19/00; B81B 7/04

(52) U.S. Cl. CPC B81B 7/008; B81B 2201/0257; B81B 7/04; H04R 19/005

(57) ABSTRACT

A MEMS microphone includes an ASIC chip, a first MEMS chip, a second MEMS chip, a housing and a circuit board. The ASIC chip is electrically connected to the first MEMS chip and the second MEMS chip, and the ASIC chip, the first MEMS chip and the second MEMS chip are mounted on the circuit board. The circuit board and the housing cooperatively form a first chamber configured to accommodate the ASIC chip and the first MEMS chip, and a second chamber configured to accommodate the second MEMS chip. The circuit board defines a first through hole corresponding to the first MEMS chip and a second through hole corresponding to the second MEMS chip. The MEMS microphone has both the function of the traditional microphone and the function of the distance sensor, which saves the space occupied by components in a mobile terminal and the cost of the components.

### CROSS REFERENCE TO RELATED APPLICATIONS

This non-provisional patent application is a continuation application of International Application PCT/CNXXXX, filed on XXX, 20XX, all contents of which are incorporated herein by reference.

### FIELD OF THE INVENTION

The present disclosure relates to the field of micro-electromechanical systems, in particular to a MEMS microphone and a mobile terminal.

### BACKGROUND

Micro-Electro-Mechanical System (MEMS) microphones are acoustoelectric transducers manufactured based on MEMS technology. MEMS microphones which have characteristics of small size, good frequency response characteristics and low noise, are becoming necessary components for mobile terminals. A MEMS microphone generally includes a MEMS chip with a capacitor and an Application Specific Integrated Circuit (ASIC) chip. The capacitance of the capacitor of the MEMS chip changes in response to input sound signals and electrical signals are generated accordingly and sent to the ASIC chip to process and output, thereby realizing picking up of the sound signals. The MEMS chip usually includes a substrate with a back cavity, and a parallel plate capacitor comprising a back plate and a diaphragm mounted on the substrate. The diaphragm receives external sound signals and vibrates consequently. As a result, the parallel plate capacitor generates a variable electrical signal, thereby realizing the conversion of sound to electricity.

During the user's answering and making a call, the phone is hung up due to the face of the user accidentally touching the screen of the mobile terminal. To solve this problem, the mobile terminal of the related art is provided with a distance sensor. When the user makes a call, the distance sensor acquires the distance of the user's body from the mobile terminal. When the distance is less than a pre-set value, the screen of the mobile terminal is controlled to turn off.

MEMS microphones in the related art have only one single function of acoustoelectric conversion. The MEMS microphone and the distance sensor in the mobile terminal are two different components which occupy a larger space and have a higher cost.

### SUMMARY

In view of the above, the present disclosure provides an improved MEMS microphone and a mobile terminal applied the improved MEMS microphone which solves at least one of the above problems.

In one aspect, the present disclosure provides a MEMS microphone which comprises at least one ASIC chip, a first MEMS chip, a second MEMS chip, a housing and a circuit board. The at least one ASIC chip is electrically connected to the first MEMS chip and the second MEMS chip. The at least one ASIC chip, the first MEMS chip and the second MEMS chip are mounted on the circuit board. The circuit board and the housing cooperatively form a first chamber configured to accommodate the ASIC chip and the first MEMS chip, and a second chamber configured to accommodate the second MEMS chip. The circuit board defines a first through hole corresponding to the first MEMS chip and a second through hole corresponding to the second MEMS chip.

In some embodiments, the housing comprises a first case and a second case spaced from the first case, the at least one ASIC chip and the first MEMS chip are received in the first case, and the second MEMS chip is received in the second case.

In some embodiments, the housing comprises a plurality of second cases in each of which at least one second MEMS chip is received.

In some embodiments, the housing is a metal housing.

In some embodiments, the at least one ASIC chip comprises an ultrasonic excitation module configured to send ultrasonic excitation signals to the second MEMS chip to enable the second MEMS chip emit ultrasonic signals.

In some embodiments, the MEMS microphone further comprises wires through which the ASIC chip is electrically connected to the first MEMS chip and the second MEMS chip.

In some embodiments, some of the wires are built in an inner layer of the circuit board to form built-in wires which are configured to electrically connect the at least one ASIC chip with the second MEMS chip.

In some embodiments, the at least one ASIC chip comprises two ASIC chips, one of the two ASIC chips being received in the first case and connected to the first MEMS chip and the other of the two ASIC chips being received in the second case and connected to the second MEMS chip.

In another aspect, the present disclosure provides a mobile terminal which comprises a MEMS microphone described above.

In some embodiments, the mobile terminal further comprises a control device configured to brighten or turn off a screen of the mobile terminal in response to the signals sent by the MEMS microphone.

The MEMS microphone of the present disclosure comprises the ASIC chip, the first MEMS chip, the second MEMS chip, the housing and the circuit board. The ASIC chip is electrically connected to the first MEMS chip and the second MEMS chip, and the ASIC chip, the first MEMS chip and the second MEMS chip are mounted on the circuit board. The circuit board and the housing cooperatively form a first chamber configured to accommodate the ASIC chip and the first MEMS chip, and a second chamber configured to accommodate the second MEMS chip. The circuit board defines a first through hole corresponding to the first MEMS chip and a second through hole corresponding to the second MEMS chip. In use, the ASIC chip sends ultrasonic excitation signals to the second MEMS chip which emits ultrasonic signals consequently. The first MEMS chip receives the ultrasonic signals from the second MEMS chip via the through holes and sends the ultrasonic signals to the ASIC chip for processing. When there is an obstacle in front of the MEMS microphone, the intensity of the ultrasonic signals received by the first MEMS chip changes due to the ultrasonic signals sent by the second MEMS chip is partly reflected by the obstacle. The distance between the MEMS microphone and the obstacle can be obtained according to the change of the intensity of the ultrasonic signals received by the first MEMS microphone chip. The MEMS microphone of the present disclosure is capable of receiving the ultrasonic signals while receiving normal acoustic signals, thereby realizing the function of the traditional microphone and the function of the distance sensor. The MEMS microphone of the present disclosure can be implemented in a mobile terminal to achieve a variety of functions, thereby saving the inner space occupied by components in the mobile terminal and reducing the cost of the components.

### BRIEF DESCRIPTION OF THE DRAWINGS

In order to explain the technical solutions of the embodiments of the present disclosure more clearly, accompanying drawings used to describe the embodiments are briefly introduced below. It is evident that the drawings in the following description are only concerned with some embodiments of the present disclosure. For those skilled in the art, in a case where no inventive effort is made, other drawings may be obtained based on these drawings.

FIG. 1 illustrates a MEMS microphone in accordance with an exemplary embodiment of the present disclosure.

FIG. 2 is a cross-sectional view taken along line A-A of FIG. 1.

FIG. 3 is an exploded view of the MEMS microphone of FIG. 1.

FIG. 4 illustrates a portable mobile terminal in accordance with another exemplary embodiment of the present disclosure.

### DESCRIPTION OF REFERENCE NUMBERS

11. ASIC chip; 12. First MEMS chip;

13. Second MEMS chip; 14. Housing;

141. First case; 142. Second case;

15. Circuit board; 16. First chamber; 17. Second chamber;

18. First through hole; 19. Second through hole; 20. Wire;

21. Built-in wire; 1. MEMS microphone; 2. Control device

### DESCRIPTION OF THE EMBODIMENTS

The technical solutions in embodiments of the present disclosure will be clearly and completely described with reference to the accompanying drawings of the present disclosure. It is evident that the elements described are only some rather than all embodiments of the present disclosure. Based on the embodiments of the present disclosure, all other embodiments obtained by those skilled in the art without making any inventive effort fall into the protection scope of the present disclosure.

The present disclosure will be further illustrated with reference to the accompanying specific embodiments.

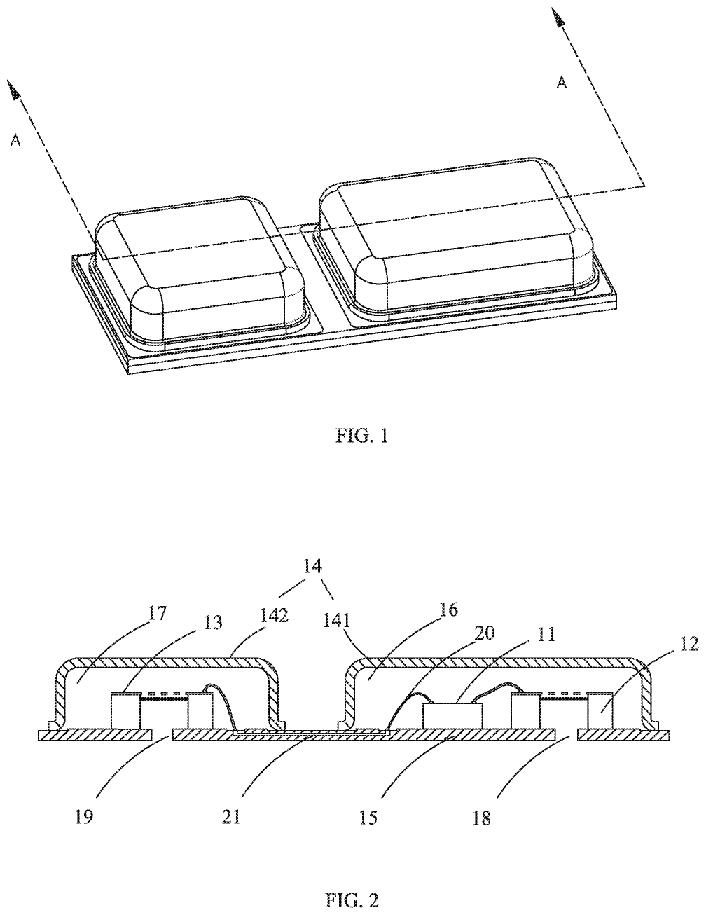

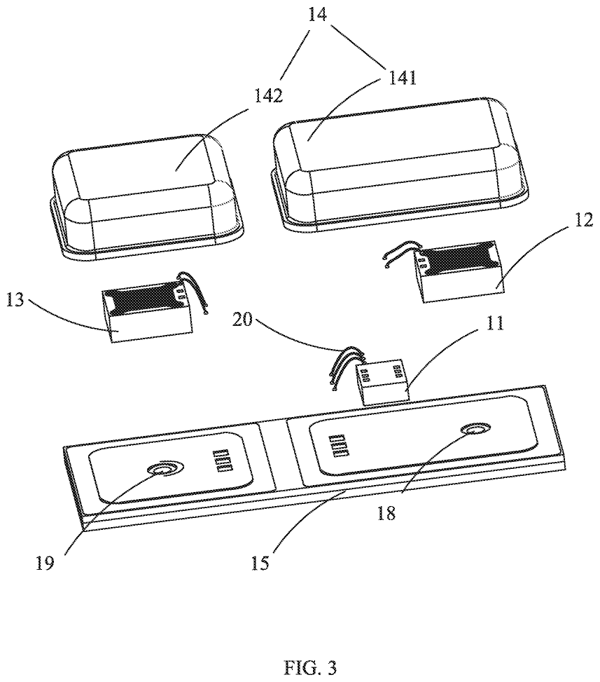

FIG. 1 illustrates a MEMS microphone according to an embodiment of the present disclosure. FIG. 2 is a cross-sectional view taken along line A-A of FIG. 1. FIG. 3 is an exploded view of the MEMS microphone of FIG. 1. Referring to FIGS. 1-3, the MEMS microphone of this embodiment of the present disclosure comprises an ASIC chip 11, a first MEMS chip 12, a second MEMS microphone 13, a housing 14, and a circuit board 15. The ASIC chip 11 is electrically connected to the first MEMS chip 12 and the second MEMS chip 13. The ASIC chip 11, the first MEMS chip 12 and the second MEMS chip 13 are mounted on the circuit board 15.

The housing 14 and the circuit board 15 cooperatively form a first chamber 16 and a second chamber 17. The first chamber 16 is configured to accommodate the ASIC chip 11 and the first MEMS chip 12. The second chamber 17 is configured to accommodate the second MEMS chip 12. The circuit board 15 defines a first through hole 18 corresponding to the first MEMS chip 12 and a second through hole 19 corresponding to the second MEMS chip 13.

In the MEMS microphone of this embodiment of the present disclosure, the ASIC chip 11, the first MEMS microphone chip 12 and the second MEMS microphone chip 13 are respectively accommodated in the two spaces formed by the housing 14 and the circuit board 15. The circuit board 15 defines through holes 18, 19 each corresponding to a corresponding space 16, 17. The second MEMS chip 13 is configured to generate sound. The first MEMS chip 12 is configured to receive sound. The ASIC chip 11 which comprises an ultrasonic excitation module is configured to send ultrasonic excitation signals to the second MEMS chip 13 through the ultrasonic excitation module to enable the second MEMS chip 13 emit ultrasonic signals which arrive at the first MEMS chip 12 after passing through the first through hole 18 and the second through hole 19. The first MEMS chip 12 receives the ultrasonic signals and transmits the received ultrasonic signals to the ASIC chip 11 for processing. When there is no obstacle in front of the MEMS microphone, the intensity of the ultrasonic signal received by the first MEMS chip 12 is A. When there is an obstacle located in front of the MEMS microphone, the intensity of the ultrasonic signal received by the first MEMS microphone chip 12 is changed to b due to the reflection of the ultrasonic signal by the obstacle. The difference between A and B can be used to detect the distance of an object away from the mobile terminal, thereby realizing the function of a distance sensor. Compared with the traditional MEMS microphone and the distance sensor, the improved MEMS microphone of the present disclosure integrating the functions of microphone and distance sensor, thereby saving the inner space occupied by components in the mobile terminal and the cost of the components.

If two MEMS chips are accommodated in the same chamber, sound generated by one of the two MEMS chips will directly interfere with sound received by the other of the two MEMS chips inside the same chamber, thereby reducing the accuracy of distance judgment. In this embodiment of the present disclosure, two MEMS chips are accommodated in two different chambers which are isolated from each other by the housing 14. One of the two MEMS chips is configured for sound generation, and the other of the two MEMS chips is configured for sound reception. The emitted sound and received sound do not interfere with each other. The sound is transmitted only through the first through hole 18 and the second through hole 19, and the distance detection of the obstacle is more accurate.

Optionally, the housing 14 is a metal housing. The housing 14 for forming the first chamber 16 and the second chamber 17 can be punched from a single piece of metal plate. That is, the part of the housing for forming the first chamber 16 and the part of the housing for forming the second chamber are connected together to form an integral structure. Alternatively, the housing 14 comprises a first case 141 and a second case 142 which are spaced apart from each other. The ASIC chip 11 and the first MEMS chip 12 are accommodated in the first chamber 16 formed by the first case 141, and the second MEMS chip 13 is accommodated in the second chamber 17 formed by the second case 142. That is, the first case 141 and the second case 142 for the first chamber 16 and the second chamber 17 are separated from each other, which makes the layout of the chips 11, 12, 13 on the circuit board 15 more flexible.

In some embodiments, the MEMS microphone comprises two ASIC chips 11, one ASIC chip 11 being accommodated in the first case 141 and connected to the first MEMS chip 12, and the other ASIC chip 11 being accommodated in the second case 142 and connected to the second MEMS chip 13. Thus, the ASIC chip 11 connected to the second MEMS chip 13 can be used to send the excitation signals to the second MEMS chip 13.

Optionally, in this embodiment, there is at least one second case 142 in each of which at least one second MEMS chip 13 is arranged. That is, there is at least one second MEMS chip 13. A plurality of second MEMS chips 13 can be respectively arranged at different positions for determining whether there are obstacles at the different positions, which is suitable for a terminal device that needs to accurately measure the position of the object. The plurality of second MEMS chips 13 may be accommodated in a single one second case 142, or accommodated in multiple second cases 142. Understandably, a plurality of ASIC chips 11 may be independently connected to the second MEMS chip 13, which makes the layout of the microphone more flexible. In practical applications, different layouts can be designed for different situations, and this embodiment does not limit the layouts of the microphone.

Optionally, the MEMS microphone of this embodiment may further include wires 20. The ASIC chip 11 is electrically connected to the first MEMS chip 12 and the second MEMS chip 13 through the wires 20.

Optionally, in this embodiment, the MEMS microphone further comprises built-in wires 21 built in the inner layer of the circuit board 15. The ASIC chip 11 is connected to the first MEMS chip 12 and the second MEMS chip 13 through the wires 20 and the built-in wires 21 arranged in the inner layer of the circuit board 15. Preferably, when the circuit board 15 is produced, the built-in wires 21 are built in the inner layer of the circuit board 15, so as to save the space on the circuit board 15 and reduce the number of connecting wires on the circuit board 15.

This embodiment provides a MEMS microphone including the ASIC chip, the first MEMS chip, the second MEMS chip, the housing, and the circuit board. The ASIC chip connects the first MEMS chip and the second MEMS chip. The ASIC chip, the first MEMS chip, and the second MEMS chip are disposed on the circuit board. The circuit board and the housing cooperatively form a first chamber and a second chamber. The first chamber is configured to accommodate the ASIC chip and the first MEMS chip, and the second chamber is configured to accommodate the second MEMS chip. The circuit board defines a first through hole corresponding to the first MEMS chip and a second through hole corresponding to the second MEMS chip. During operation, the ASIC chip sends ultrasonic excitation signals to the second MEMS chip which emits ultrasonic signals consequently. The first MEMS chip receives the ultrasonic signals from the second MEMS chip via the through holes and sends the ultrasonic signals to the ASIC chip for processing. When there is an obstacle located in front of the MEMS microphone, the intensity of the ultrasonic signals received by the first MEMS chip changes due to the ultrasonic signals sent by the second MEMS chip being partly reflected by the obstacle before arriving at the first MEMS chip. The distance between the MEMS microphone and the obstacle can be obtained according to the change of the intensity of the ultrasonic signals received by the first MEMS microphone chip. The MEMS microphone of the present disclosure is capable of receiving the ultrasonic signals while receiving normal acoustic signals, thereby realizing both the function of the traditional microphone and the function of the distance sensor. The MEMS microphone of the present disclosure can be implemented in the mobile terminal to achieve a variety of functions, which saves the inner space occupied by components in the mobile terminal and reduces the cost of the components.

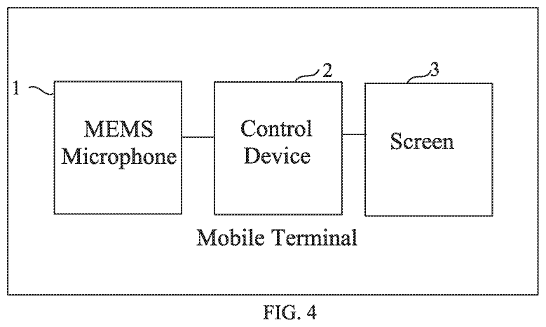

FIG. 4 is a schematic diagram of a mobile terminal according to another embodiment of the present disclosure. Referring to FIG. 4, the mobile terminal includes the above-described MEMS microphone 1 and a control device 2 configured to brighten or turn off a screen 3 of the mobile terminal in response to the signals sent by MEMS microphone 1. Alternatively, the MEMS microphone 1 may also be applied for gesture recognition control in mobile terminals

In the mobile terminal of the present disclosure, the conventional microphone and the distance sensor are replaced with the improved MEMS microphone according to an embodiment of the present disclosure. During a call, when the user's face is close to the screen of the mobile terminal, the improved MEMS microphone 1 having functions of the conventional microphone and the distance sensor provides ultrasonic signals with different intensity to the control device 2. If the distance between the user's face and the mobile terminal screen is less than the pre-set value, the control device 2 controls the screen of the mobile terminal to turn off. If the distance between the user's face and the mobile terminal screen is not less than the pre-set value, the control device 2 controls the mobile terminal to brighten the screen, so as to avoid that the user hangs up the phone due to the face accidentally touching the screen of the mobile terminal during a call. Compared with the traditional MEMS microphone and the distance sensor, the improved MEMS microphone integrates both the function of microphone and the function of distance sensor, which saves the space occupied by components in the mobile terminal and saves the cost of the components.

The above-described are only embodiments of the present disclosure. It shall be noted that those skilled in the art may make improvements without departing from the spirit or scope of the present disclosure. All these improvements fall into the protection scope of the present disclosure.

What is claimed is:

1. A MEMS microphone comprising at least one ASIC chip, a first MEMS chip, a second MEMS chip, a housing and a circuit board;
wherein the at least one ASIC chip is electrically connected to the first MEMS chip and the second MEMS chip, and the at least one ASIC chip, the first MEMS chip and the second MEMS chip are mounted on the circuit board; and
wherein the circuit board and the housing cooperatively form a first chamber configured to accommodate the at least one ASIC chip and the first MEMS chip, and a second chamber configured to accommodate the second MEMS chip, the circuit board defining a first through hole corresponding to the first MEMS chip and a second through hole corresponding to the second MEMS chip.

2. The MEMS microphone of claim 1, wherein the housing comprises a first case and a second case spaced from the first case, the at least one ASIC chip and the first MEMS chip are received in the first case, and the second MEMS chip is received in the second case.

3. The MEMS microphone of claim 2, wherein the housing further comprises additional second cases, and at least one second MEMS chip is received in each of the second cases.

4. The MEMS microphone of claim 1, wherein the housing is a metal housing.

5. The MEMS microphone of claim 1, wherein the at least one ASIC chip comprises an ultrasonic excitation module configured to send ultrasonic excitation signals to the second MEMS chip to enable the second MEMS chip emit ultrasonic signals.

6. The MEMS microphone of claim 1, further comprising wires through which the at least one ASIC chip is electrically connected to the first MEMS chip and the second MEMS chip.

7. The MEMS microphone of claim 6, wherein some of the wires are built in an inner layer of the circuit board to form built-in wires which are configured to electrically connect the at least one ASIC chip with the second MEMS chip.

8. The MEMS microphone of claim 2, wherein the at least one ASIC chip comprises two ASIC chips, one of the two ASIC chips being received in the first case and connected to the first MEMS chip, the other of the two ASIC chips being received in the second case and connected to the second MEMS chip.

9. A mobile terminal comprising a MEMS microphone of claim 1.

10. The mobile terminal of claim 9, further comprising a control device configured to brighten or turn off a screen of the mobile terminal in response to the signals sent by MEMS microphone.
